(19) United States
(12) Patent Application Publication
(10) Pub. No.: US 2002/0134914 A1
(43) Pub. Date: Sep. 26, 2002

(54) Uniform data card illumination for optical reader

(76) Inventors: Francis P. Ziemba, Madison, WI (US); Barry J. Howe, Middleton, WI (US)

Correspondence Address: WHYTE HIRSCHBOECK DUDEK S C, 111 EAST WISCONSIN AVENUE, SUITE 2100, MILWAUKEE, WI, 53202

(21) Appl. No.: 09/816,972

(22) Filed: Mar. 23, 2001

(51) Int. Cl. H01L 27/00

(52) U.S. Cl. 250/208.1

(57) ABSTRACT

An optical system for providing substantially uniform illumination of an object, such as a data card. The optical system provides the folding of an optical path through a series of angled mirrors placed within the housing. Uniform illumination is provided by a pair of light sources within each of a pair of side panels inserted in the side of the housing. Preferably the light sources are white light emitting diodes. The light panels may include abrasions to better diffuse and scatter the light emitted from the light sources. The light panels are placed such that they do not interfere with the reflected optical paths of the mirrors. The images on the data card are reflected by the mirrors to a lens, and ultimately to an imaging chip. The invention allows the use of a less expensive lens as well as white light sources such that both black and white and color images and information may be read from the desired object, such as a data card.

### BACKGROUND OF THE INVENTION

The present invention relates generally to optical reading systems, and more particularly to an optical reading system, for reading a data card, that uniformly illuminates the data card from light sources not in the optical imaging path of the data card. The present invention utilizes laterally positioned light sources to illuminate a data card and a folded optical system within a compact housing. The card is optically read by an image sensor. Such a system may be part of a biometric verification process.

The field of biometrics, or the measuring of physical characteristic used to recognize the identity or verify the claimed identity of an individual, has emerged as an increasingly reliable methodology for verification (1 to 1) and identification (1 to many) of individuals. Biometrics has become a very powerful tool in the solving of problems associated with acquiring positive identification of individuals. Increasingly, in biometrics as well as in other fields, information related to the individuals which utilize such systems is stored on a data card. Such information may include the enrollment information of the individual, i.e., name, personal information, identification numbers, fingerprint enrollment data, including fingerprint minutia types, fingerprint minutia location data (the positioning of ridge endings and ridge bifurcations), images of the individual, as well as any other desired data. Some information may be uncoded, and overtly read, while other information may be coded, such as in a two dimensional (2-D) barcode symbology patch (such as a PDF 417 or a dataglyph).

In an optical system, it is necessary to transform the information on the data card onto an imaging camera chip. This requires that the image on the data card, whether part of a PDF patch or otherwise, be projected onto an image sensor. This translates, for a standard credit card size plastic card (3 3/2 inches by 2 inches) being turned into an image typically approximately ½ inch by ⅓ of an inch. Therefore, the diagonal of the data card must be able to be transmitted to fit into the diagonal of the sensor. This results in reduction factors on the order of 6-7, obtained by the ratio of the object card diagonal to the image size diagonal. In order to provide the desired reduction, and maintain a low cost, compact optical system, it is necessary to have a relatively large optical distance from the imaging camera chip to the object or data card. Therefore, there exists a need to be able to use low cost, commercially available lenses wherein the optical path length between the data card and the image sensor may be fit into a commercially desirable and feasible package.

Another problem with optical systems is that, for color or black and white images, individual color differentiation is difficult due to non-uniform illumination across a data card. The non-uniform illumination is due to the light source positioning, which contributes to difficulties in reading variable contrast images. This is, in part, due to the fact that the lighting sources are on the sides of a light box containing the optical systems, and therefore, are out of the optical imaging path. Therefore, the light source is at an angle, and perhaps even perpendicular to, the object (the data card) it is illuminating.

Typically, electroluminescent panels are used that emit nearly monochromatic light. However, now, more then ever, more information, and in different forms are being stored on data type cards, such as color images, as well as other type information. It is also difficult to illuminate the data cards properly with electroluminescent light sources, and these light sources are inadequate to read full spectrum images. Therefore, it is necessary that the light source be a full spectrum or white light source in order to be utilized with color imaging components. Particularly, color imaging chips are increasingly being used as the image sensors. It is decreasingly preferred to use monochromatic illumination because of the limitations of what can be read on a particular data card. By using the full spectrum white light source, the system is able to reproduce and read whatever information is on the data card, including the capturing of color images.

Therefore, there exists the need for an optical reader system that is compact, utilizes readily available white light sources, and provides uniform illumination of a data card to permit reading of any data, black and white, images and text, and color images that are illuminated. In this manner, the optical system can utilize a color image camera to read information on the data card.

### SUMMARY OF THE INVENTION

The present invention provides a uniform data card illumination system that overcomes the aforementioned problems, and allows the reading of color data cards with commercially available lenses and optical systems.

In accordance with one aspect of the invention, an optical system for uniform illumination and reading of a data card is disclosed. The optical system includes a color image sensor, a folded optical system for imaging the data card onto the image sensor, and a data card illumination system that provides substantially uniform illumination of the data card.

In accordance with another aspect of the invention, an optical system for reading a data card or other object includes an image sensor and a lens for reading the object. The lens and object define an physical distance therebetween. The lens and object also define an object focal distance as a distance of the optical path from the object to the lens. The optical system includes a plurality of reflective surfaces, with each reflective surface positioned, in combination, to reflect an image of the object. The physical distance between the lens and the object is less than the optical focal distance.

In accordance with another aspect of the invention, an optical system for reading an object is disclosed. The system includes a housing having an interior and an exterior, the exterior partially defined by an at least partially transparent object placement surface, which is receptive to the object. A group of mirrored surfaces are positioned within the housing to reflect an image of the object which is positioned on the object placement surface. The system includes a lens positioned to receive the image reflected by the mirrored surfaces, and an imaging sensor for receiving the image through the lens. A pair of lighting panels are at least partially positioned within the housing interior. Each lighting panel is adapted to receive a plurality of light sources therein. The light sources emit light through faces of the light panels into the interior of the housing and onto the object. The light sources also are positioned within the light panels such that the light sources are not located within the interior of the housing.

A method of reading a data card and a method of illuminating a data card are also provided.

Various other features, objects and advantages of the present invention will be made apparent from the following detailed description and the drawings.

### BRIEF DESCRIPTION OF THE DRAWINGS

The drawings illustrate one embodiment presently contemplated for carrying out the invention.

In the drawings:

FIG. 1 is an exploded view of an optical system in accordance with the present invention;

FIG. 2 is a perspective view of an assembled optical system of FIG. 1 in use with a data card;

FIG. 3 is a front, partial cross-sectional view of FIG. 2 illustrating the uniform illumination panels;

FIG. 4, is a side cross-sectional view illustrating the folded optical path of the imager;

FIG. 5 is an enlarged view of a portion of FIG. 4 further illustrating the optical path in accordance with the present invention;

FIG. 6 illustrates a light panel in accordance with one aspect of the invention;

FIG. 7 is a sectional view taken along lines 7-7 of FIG. 6.

FIG. 8 is a diagram illustrating the optical principals of the present invention;

FIG. 9, is a diagram illustrating an optical path length involving one aspect of the present invention;

FIG. 10, is a diagram illustrating the folding of an optical path in accordance with the present invention.

### DETAILED DESCRIPTION OF THE DRAWINGS

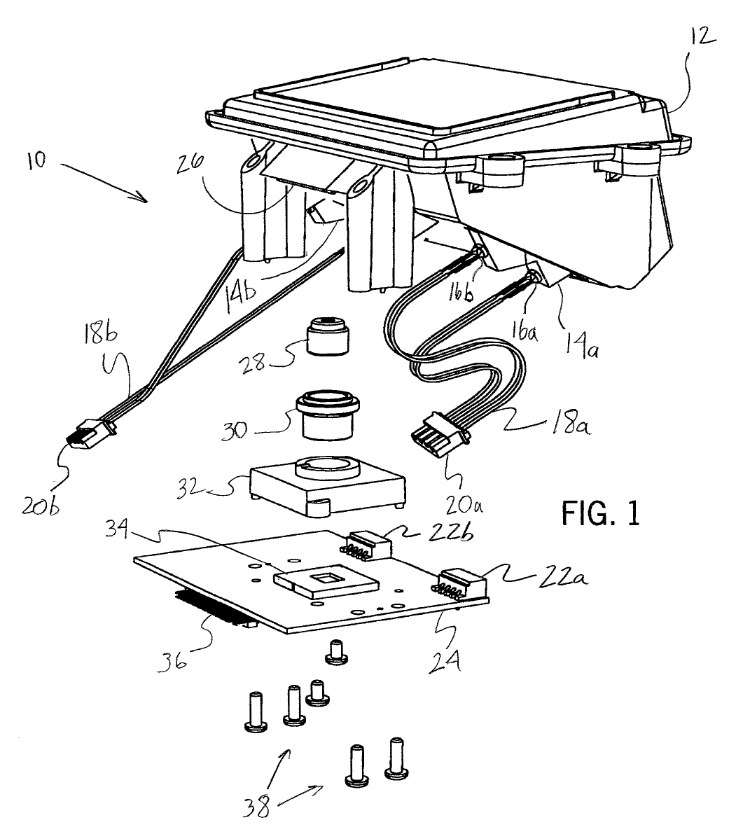

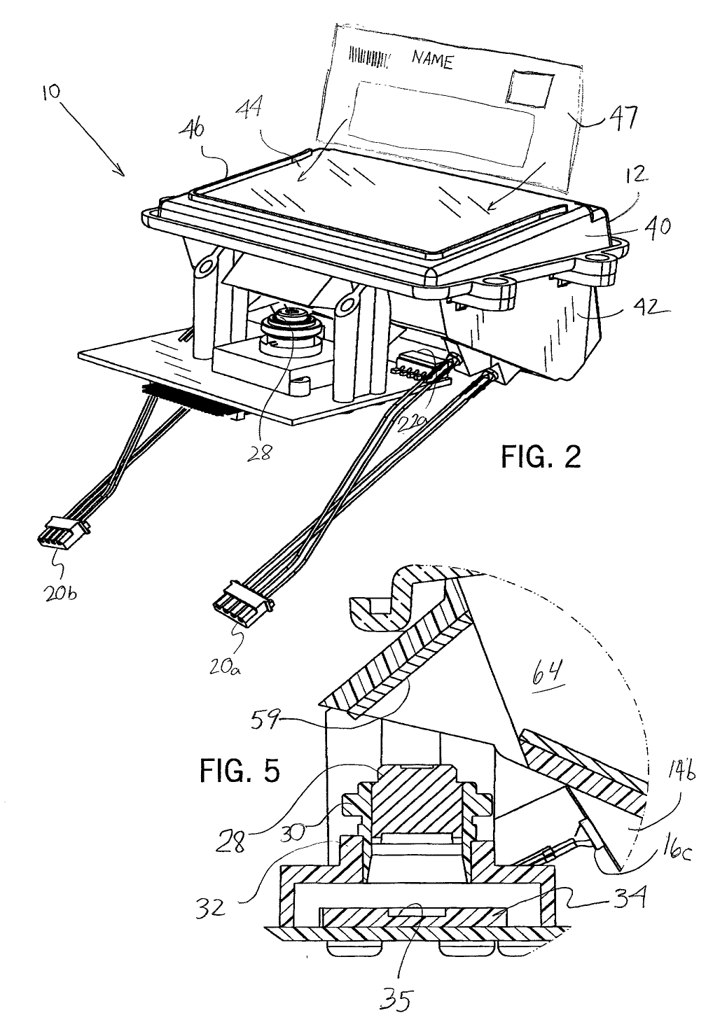

Referring now to FIG. 1, an optical system in accordance with the present invention is showing generally by the numeral 10. Optical system 10 is useful in the area of biometrics, which is the system of utilizing an individual's unique physical characteristics in order to authenticate that person's identity. Such biometric information may be stored on a data card, for example (47 of FIG. 2). Biometric information, as well as other information, may be stored on the data card, including name, identifying information, pictures or other images, as well as fingerprint images. Generally speaking, any information that can be placed on a credit card style data card, which may be optically read, is contemplated by the present invention. Optical system 10 is shown in an exploded view. Optical system 10 is used to optically read the information on the data card. Optical system 10 includes a housing 12. Housing 12, it is contemplated and preferred, is constructed of a plastic (injection molded or otherwise) or other transparent material, although any suitable material may be employed. Extending from the interior of housing 12 is a pair of light panels 14a and 14b. Positioned at least partially within each light panel, 14a and 14b is a pair of light sources 16a and 16b. Light sources 16a and 16b are preferably light emitting diodes (LEDs) that preferably emit substantially white light. The LEDs may be placed in the light panels by a clear epoxy or other adhesive such that there are no air pockets within the space provided for the LEDs. The white light is preferred because of the availability and desirability of color cameras and imaging chips for reading images, which require white light, even for black and white images. The direction and position of the light sources are arranged to take advantage of the internal reflections within the light panels 14a and 14b. It is preferred that two light sources 16a and 16b are used in each of the light panels, for a total of four white light sources. However, any number of light sources may be utilized to achieve the desired lighting effects. Light sources 16a and 16b (as well as the light sources for light panel 14b) are connected to connecting circuitry 18a and 18b to electrical connectors 20a and 20b. Connectors 20a and 20b are received into mating connectors 22a and 22b respectively to provide an electrical connection between light sources 16a and 16b (and 14a and 14b) and printed circuit board 24. Images of data cards laid on housing 12 via reflective surface 26 are reflected to lens 28. Lens 28 is held by adapter bushing 30 in lens holder 32. In operation, lens 28 focuses any image it receives onto optical imager 34. Optical imager 34 (or alternatively image sensor or imaging chip) may be a CMOS imager or a CCD imager. Preferably, with the advent of color imaging chips, optical imager 34 is preferably capable of reading color images. It is also possible that a monochromatic imaging chip may be used. This sensor information is transmitted via a system connection 36 to an electronic system computer or other part of a biometric reader, for example. Printed circuit board 24 is attached to lens holder 32 and housing 12 by fasteners 38 in a conventional manner.

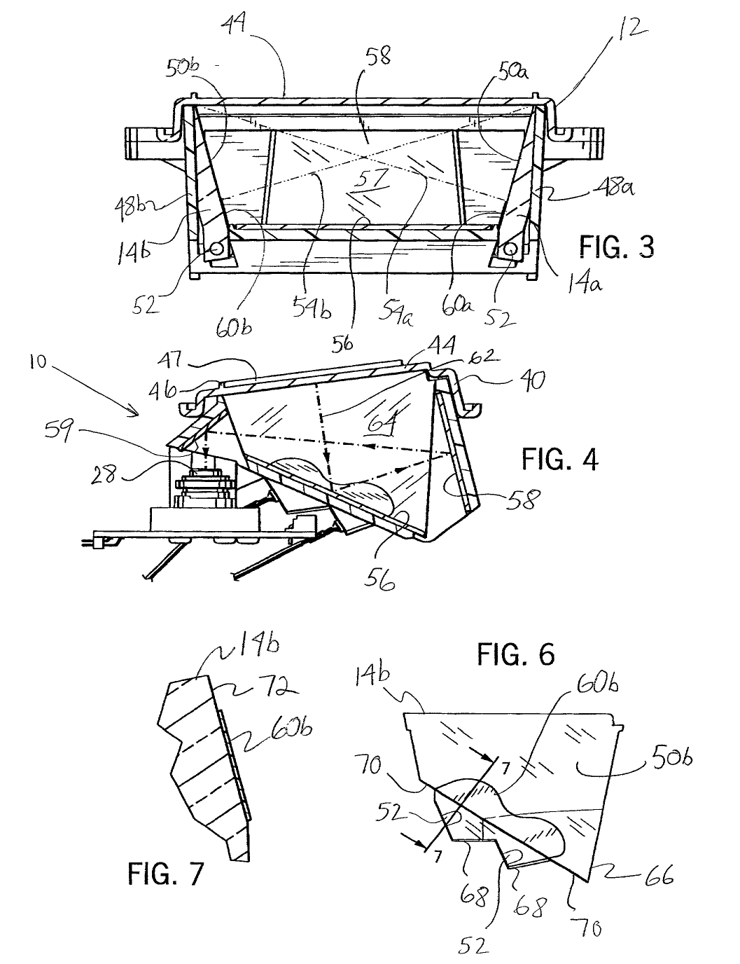

Referring now to FIG. 2, an optical system 10 is shown in an assembled position (except with connectors 20a and 20b not connected to mating connectors 22a and 22b). Housing 12 includes an upper portion 40 connected to a lower portion 42. Together, upper portion 40 and lower portion 42 define an interior (57 of FIG. 3) of housing 12. Included in housing upper portion 40 is a top surface or object placement surface 44. Surface 44 is a data card reading surface, as top surface 44 is transparent or antireflection coated in a preferred embodiment, and anything placed upon it will be read. Surface 44 is bounded in part by ridge 46, which extends substantially around the perimeter of surface 44. In operation of optical system 10, a data card 47 or other type card is placed onto top surface 44 such that outer ridge 46 places data card 47 in a correct positioning. Data card 47 may contain any information that is desired to be optically read, including color images or pictures (including photo identification pictures), PDF patches or other two dimensional bar code symbologies, names, identifying numbers, including social security numbers, driver license numbers etc. or any other data that it desired to be read. The goal is that the information from the data card is focused by lens 28 to be read by the optical imager (34 of FIG. 1).

Referring now to FIG. 3, a section of front view is shown with the optical system removed for illustration purposes. The goal is to be able to uniformly illuminate a data card or any other object to be placed on top surface 44 of housing 12. Housing 12 also includes two sidewalls 48a and 48b. Inserted into housing 12 and adjacent to each sidewall 48a and 48b are light panels 14a and 14b as part of an card illumination system. Each light panel includes a pair of openings 52 within each light panel 14a and 14b to receive the light sources 16a and 16b of FIG. 1 therein. Surfaces 50a and 50b are treated such that light emitted from the light sources will be emitted therethrough. For example, surfaces 50a and 50b may be subject to abrasions or other microtextures in order to scatter light out of the light panels 14a and 14b and illuminate the card. Such abrasions or microtexturing may be effected by sanding, sandblasting, molding, frosting or other roughening method that results in scattering externally, rather than internally reflecting. Light emerging from surface 50a and 50b will illuminate top surface 44 as generally bounded by trajectory 54a from light panel 14a and 54b from light panel 14b. The result is a substantially uniform illumination of any flat object or, for example, a data card placed upon top surface 44. The illumination of top surface 44 from light sources along the side of housing 12 is important because it prevents any light source from blocking the optical path from the card placed on top surface 44. The optical path is not blocked and the card image is reflected by mirrored surface 56 and then to mirrored surface 58 as part of the optical path. Light is not emitted from light panels 14a and 14b in a preferred embodiment where tabs or antiglare light source masks 60a and 60b are placed. This placement of the masks is to maximize uniform illumination of top surface 44 and minimize any glare or “bright spots” that may occur within housing 12, which tend to prevent an accurate optical reading of a data card or other object.

Referring now to FIG. 4, an optical path 62 is illustrated for optical system 10. As previously described, data card 47 is placed onto top surface 44 such that it rests against ridge 46 of housing upper portion 40. The image on data card 47, now having substantially uniform illumination, enters the interior or lighting chamber 64 of optical system 10. Within the interior or lighting chamber 64, a series of angled mirrors, preferably three (representative of an image reflection system, or other relflective surface), reflects the image from data card 47 ultimately to lens 28. The optical path from the image to the lens in a preferred embodiment is substantially 4.5 inches (11.43 cm). The physical distance between the image and the lens in a preferred embodiment is substantially 1.75 inches (4.45 cm). The angled mirrors 56, 58 and 59, in this embodiment, form a substantially triangular configuration such that multiple reflections of the image of data card 47 may be made prior to entering lens 28. The image initially traveling along optical path 62 is reflected by first mirror 56, and then to mirror 58, located in the back of the interior 64 of housing 12. The image is then reflected to mirror 59, which reflects it to lens 28. In this manner, the optical path between the object and the lens may be longer than the physical distance therebetween.

Referring now to FIG. 5, a section of FIG. 4 is highlighted. A portion is cut away for further clarification. Images that are reflected from mirror 59 are transmitted to lens 28. Lens 28 is held by lens holder 32 and adapter bushing 30. With lens 28, the card image is focused onto optical imager 34 having optical chip 35 therein. The purpose of optical system 10 is to reflect as accurate and true representation of the image on data card 47 as possible, no matter what color or shade the image is. Also, light source 16c is positioned in light panel 14b such that the light emitted from light will be emitted into interior 64 but the light source 16c is positioned outside the interior 64 of the housing.

Referring now to FIG. 6, light panel 14b is illustrated. Light panel 14a has similar but opposite features, as they are placed in on opposing sides of housing 12. Light panel 14b is generally tapered at one end 66, but may be any suitable shape to fit within housing 12, and includes several generally triangular and downwardly extending projections 68. Each downwardly extending projection 68 includes the openings 52 for receiving the light sources therein. When light panel 14b in inserted into its housing, extending projections 68 fit within the housing such that edge 70 forms the bottom of the portion of light panel 14b that is exposed to the interior or lighting chamber (64 of FIG. 4) of housing 12. In this manner, although the light sources are within and part of light panel 14b, the light sources within openings 52 are not within the interior 64 of housing 12. This prevents any light emitted from the light sources to interfere with the uniform illumination patterns desired, by not causing any unwanted bright spots. Light panel 14b may take on any general shape, but is shaped with a preferred embodiment to fit within the sidewalls of the housing to which it will be placed. Light panel 14b further includes, in a preferred embodiment, antiglare or masking tabs 60b to further prevent undesired lighting patterns within interior of the housing. Light panel 14b preferably includes a textured surface 50b in order to properly scatter light emitted from light panel 14b.

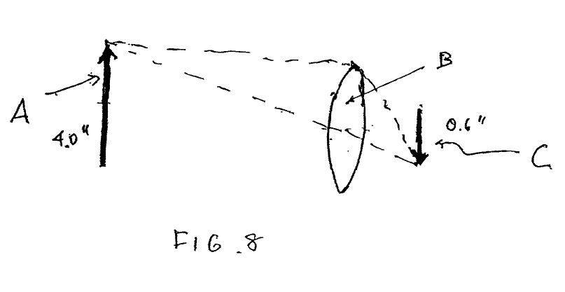

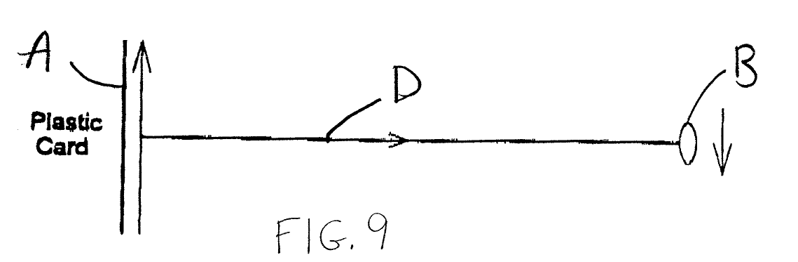

Referring now to FIG. 7, which is taken along lines 7-7 of FIG. 6., a cross sectional view of light panel 14b shows the placement of antiglare or masking tab 60b on its surface to mask at least a portion of the light leaving light panel 14b, to prevent the undesirable bright spots that preclude uniform illumination. Antiglare tab 60b allows more direct light to be emitted from noncovered surface 72 of light panel 14b.

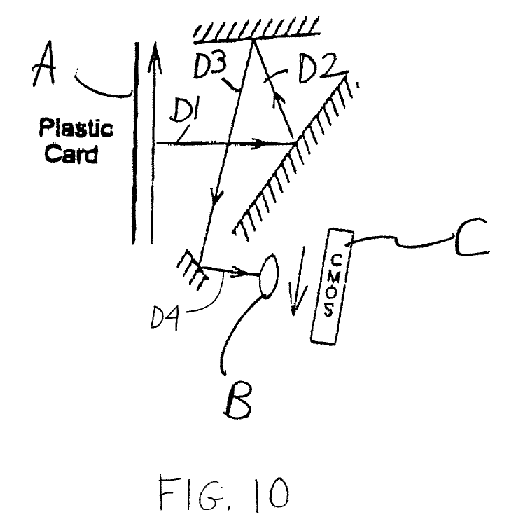

Referring now to FIG. 8, the diagram illustrates the theoretical optical transmission that is occurring. In Image A, such as a data card or standard credit card size, which measures a diagonal of approximately 4.3 inches (10.24 cm), light must pass through a lens B to be focused on a sensor C having a diagonal of approximately 0.6 inches (1.52 cm). This results in a reduction factor of approximately 6⅔ or ratio of the object size (or data card) to the image size (the CMOS optical chip size). FIG. 9 illustrates that in order to accomplish such a reduction, object A, in this instance a plastic data card, would require a particular optical path length D from the lens B in order to accomplish the particular reduction factor or ratio. In FIG. 9 the physical distance equals the optical path length D. The theory behind the present invention, as demonstrated in FIG. 10, is to fold the optical distance from the image A (a data or other plastic card) to the lens B before focusing the image onto the image chip C. The result is that the distances D1, D2. D3 and D4, are summed together to form distance D of FIG. 9. However, the result is that the physical distance between image A and lens B is substantially reduced, such that the entire apparatus may be placed in a commercially viable packaging. An additional benefit is that lens B is of a lower cost because the cost of lenses is inversely proportional to the amount of optical path necessary to provide the appropriate reduction factor desired. Therefore, while the physical distance of image A to the lens B is reduced, a low cost lens B may be utilized because of the bending and folding of the optical path into reflected segments.

The present invention includes several methods. One method is a method of reading a data card. The method includes providing a data card having a readable image, a lens and an optical image chip to read the image, and uniformly illuminating the data card image. The invention includes serially reflecting the data card image with a series of mirrors to the lens and the optical imaging chip. Preferably, the reflecting step includes serially reflecting the image with three mirrors positioned to serially reflect the image from the data card, to each of the individual mirrors, and then to the lens and CMOS imager. The illuminating is preferably performed with white LEDs.

The present invention also contemplates a method of illuminating a data card, which includes the steps of inserting a data card to be read by an optical sensor and providing a housing having a plurality of sidewalls, an interior and an exterior. The method includes inserting a light source into a panel to emit visible light, and roughening at least one surface of the panel to facilitate light transmission therethrough. The panels are inserted into the housing and positioned adjacent the sidewalls of the housing such that the panels transmit the visible light emitted from the light source from opposing sides of the interior of the housing.

The present invention has been described in terms of the preferred embodiment, and it is recognized that equivalents, alternatives, and modifications, aside from those expressly stated, are possible and within the scope of the claims.

What is claimed is:

1. An optical system for uniform illumination and reading of an image comprising:
an image sensor;
an image reflection system for reflecting the image to the image sensor; and
an image illumination system that provides substantially uniform illumination of the image.

2. The optical system of claim 1, where the image reflection system comprises a plurality of angled mirrored surfaces.

3. The optical system of claim 2, wherein each mirrored surface is angled such that it reflects the image from or to another of the plurality of angled mirrored surfaces.

4. The optical system of claim 2, wherein there are three angled mirrored surfaces.

5. An optical imaging apparatus for reading a data card comprising:
a housing having at least one reflective surface therein;
a plurality of light sources for generating light within the housing;
a plurality of panels within the housing having at least a portion of the light sources therein and including a microtextured surface for emitting light generated by the light sources through the microtextured surface to provide substantially uniform illumination of the data card;
wherein the at least one reflective surfaces reflect an image of the data card illuminated by the light sources and panels.

6. An optical imaging apparatus comprising:
a housing;
a plurality of light sources;
wherein the housing includes at least one panel inserted therein, the at least one panel having the plurality of light sources contained at least partially therein, the light sources emitting visible light through the panel.

7. The optical imaging apparatus of claim 6, wherein the panel includes at least one surface having abrasions thereon to permit light from the light sources to pass therethrough.

8. The optical imaging apparatus of claim 6, wherein the light sources emit substantially white light.

9. The optical imaging apparatus of claim 6, wherein the light sources are light emitting diodes (LEDs).

10. The optical imaging apparatus of claim 6, further including at least one masking tab attached to at least one of the panels to mask at least a portion of the light emitted from the light sources to provide substantially uniform illumination of the housing.

11. An optical system comprising:
a housing having an exterior and an interior;
a plurality of mirrors positioned to reflect an image placed on the exterior of the housing;
an imaging system for receiving the image reflected by the plurality of mirrors; and
a white light source for illuminating the image.

12. The optical system of claim 11, wherein the imaging system includes a lens and an optical imaging chip.

13. The optical system of claim 12, wherein the optical imaging chip is a CMOS image sensor.

14. The optical system of claim 12, wherein the optical imaging chip is a CCD image sensor.

15. The optical system of claim 12, wherein the image has an image diagonal and the optical imaging chip has a chip diagonal and wherein the ratio of the image diagonal to the chip diagonal is substantially 6⅔.

16. The optical system of claim 15, wherein the image diagonal is substantially 4.03 inches (10.24 cm).

17. The optical system of claim 15, wherein the chip diagonal is substantially 0.6 inches (1.52 cm).

18. The optical system of claim 12, wherein the image and the lens defines an optical path length and a physical distance therebetween; and
wherein the physical distance between the image and the lens is less than the optical path length.

19. The optical image system of claim 18, wherein the optical path length is substantially 4½ inches (11.43 cm).

20. The optical system of claim 18, wherein the physical distance between the image and the lens is substantially 1¾ inches (4.45 cm).

21. The optical system of claim 11, further including at least one illumination panel placed within the interior of the housing to reflect light generated by the light source, the panel including a plurality of surfaces, wherein at least one of the surfaces includes abrasions to allow light from the light source to be emitted from the panel.

22. The optical system of claim 11, wherein the light source is positioned outside the interior of the housing so as to provide light within the interior without the light source being physically within the interior of the housing.

23. The optical system of claim 21, wherein the light source is positioned within the panel.

24. An optical system for reading an object comprising:
an image sensor;
a lens for reading the object, the lens and object defining a physical distance therebetween, and an object focal distance as a distance of the optical path from the object to the lens;
a plurality of reflective surfaces, each reflective surface positioned, in combination, to reflect an image of the object to the lens, wherein the physical distance between the lens and object is less than the optical focal distance.

25. The optical system of the claim 24, wherein the plurality of reflective surfaces includes three mirrors.

26. An optical system comprising:
a housing having an interior, the interior having a plurality of reflective surfaces;
a pair of illuminating surfaces;
at least one light source; and
an optical imager for reading an object placed on the housing as reflected by the reflective surfaces.

27. The optical system of claim 26, wherein the at least one light source emits substantially white light.

28. The optical system of claim 26, wherein the at least one light source is a light mitting diode (LED).

29. The optical system of claim 26, wherein there are four light sources.

30. The optical system of claim 26, wherein the pair of illuminating surfaces are at least partially marked with abrasions.

31. The optical system of claim 26, wherein the pair of illuminating surfaces each include a masking tab attached thereto to partially mask the light emitted from the at least one light source.

32. A method of reading a data card comprising steps of:
providing a data card having a readable image, a lens and an optical image chip to read the image;
uniformly illuminating the image; and
serially reflecting the image with a series of mirrors to the lens and the optical imaging chip.

33. The method of claim 32, wherein the reflecting step includes serially reflecting the image with three mirrors positioned to serially reflect the image from the data card, to each of the individual mirrors, and then to the lens.

34. The method of claim 32, wherein the illuminating step is performed with light emitting diodes (LED) that emit a substantially white light.

35. A method of illuminating a data card comprising the steps of:
inserting a data card to be read by an optical sensor;
providing a housing having a plurality of sidewalls, an interior and an exterior;
inserting a light source into a panel to emit visible light;
roughening at least one surface of the panel to facilitate light transmission therethrough; and
inserting the panel into the housing and positioning the panel adjacent the sidewalls of the housing such that the panels transmit the visible light emitted from the light source from opposing sides of the interior of the housing.

36. The method of claim 35, wherein the housing and panel is one of transparent, semi-transparent or translucent.

37. An optical system for reading an object comprising:
a housing having an interior and an exterior, the exterior partially defined by an at least partially transparent object placement surface, the object placement surface receptive to the object;
a group of mirrored surfaces positioned within the housing to reflect an image of the object on the object placement surface;
a lens positioned to receive the image reflected by the mirrored surfaces;
an imaging sensor for receiving the image through the lens;
a pair of lighting panels at least partially positioned within the housing interior, each lighting panel adapted to receive a plurality of light sources therein, the light sources emitting light through the light panels into the interior of the housing and onto the object, the light sources positioned within the light panels such that the light sources are not located within the interior of the housing.

38. The optical system of claim 37, further including a light source mask applied to each of the light panels to block a portion of the light emitted from the light source into the interior of the housing.

39. The optical system of claim 37, wherein the light panels are on opposing sides of the housing.

40. The optical system of claim 37, wherein the light sources are light emitting diodes that emit substantially white light.

41. The optical system of claim 37, wherein the image includes biometric information.

42. The optical system of claim 37, wherein the object is a data card.
